(19) United States
(12) Patent Application Publication
(10) Pub. No.: US 2012/0235549 A1
(43) Pub. Date: Sep. 20, 2012

(54) FAN MOUNTING APPARATUS FOR HEAT DISSPATION

(75) Inventors: KUN-CHI HSIEH, Tu-Cheng (TW); LI TONG, Wuhan City (CN); XING ZHAO, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/290,055

(22) Filed: Nov. 4, 2011

(30) Foreign Application Priority Data
Mar. 18, 2011 (CN) 201110065808.4

(51) Int. Cl. H05K 7/20; H05K 5/02

(52) U.S. Cl. 312/223.2

(57) ABSTRACT

A fan mounting apparatus comprises a computer case having a bottom plate, and a rear plate connected to the bottom plate; the rear plate comprising a flange; the flange comprising a connecting panel extending towards the bottom plate, and a clamping panel extending from the connecting panel towards the bottom plate; a bracket comprising a main body, a clipping portion, and a mounting portion; the clipping portion and the mounting portion are on opposite sides of the main body; the mounting portion comprising a hook; wherein the clipping portion is attached to the bottom plate, the mounting portion is deformable, the hook has a configuration to extend through the clamping panel when the mounting portion is deformed, the clamping panel has a configuration to abut on an outer surface of the hook and is adapted to prevent the bracket from moving away from the rear plate.

### BACKGROUND

1. Technical Field

The present disclosure relates to fan mounting apparatuses, more particularly to a fan mounting apparatus for a computer system.

2. Description of Related Art

In a working computer system, a large amount of heat may be generated from electrical elements of the computer system. A fan is often used as a conventional means to dissipate the heat from the computer system. Typically, a bracket is provided for receiving a fan, and a plurality of screws may be used to install the fan to the bracket. However, in such a mounting configuration, assembling and disassembling of the fan may be inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a mounting apparatus and a fan in accordance with an embodiment.

FIG. 2 is an exploded, isometric view of a bracket of the mounting apparatus and the fan of FIG. 1.

FIG. 3 is an assembled view of the mounting apparatus and the fan of FIG. 2.

FIG. 4 is an assembled view of the mounting apparatus and the fan of FIG. 1.

FIG. 5 is a cross-sectional view in an enlarged scale taken along line V-V of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

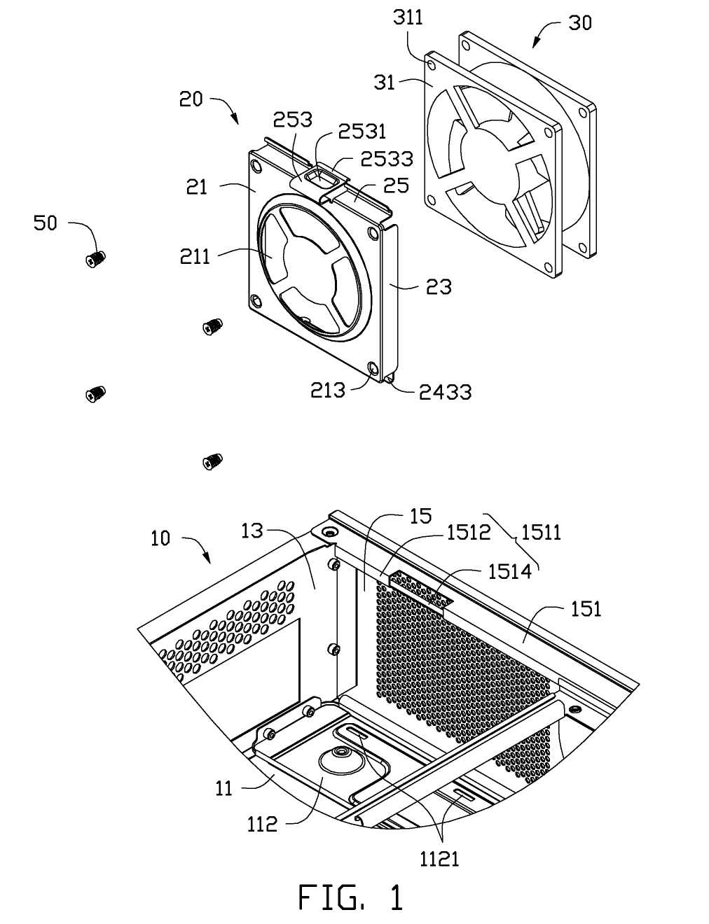

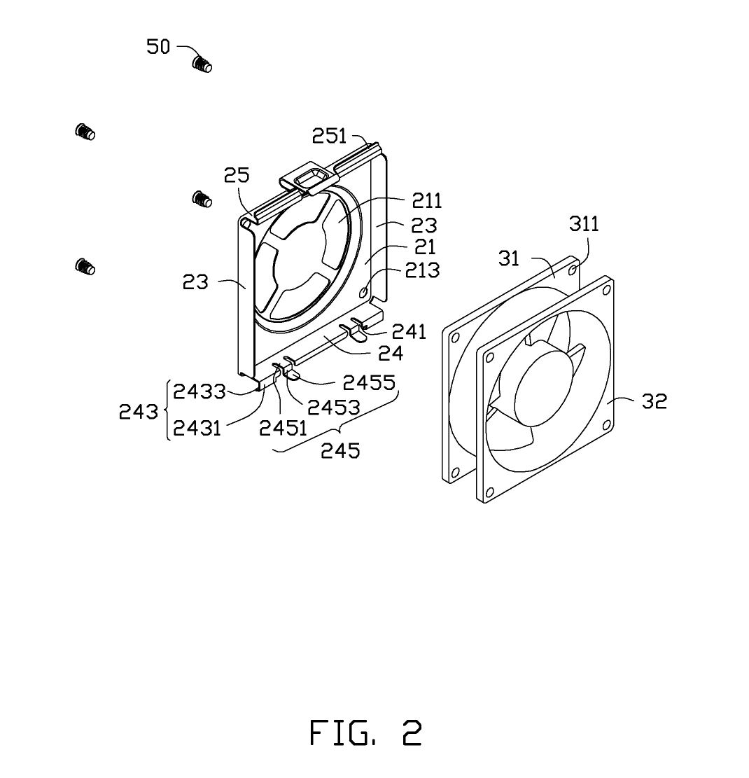

Referring to FIGS. 1 and 2, a mounting apparatus in accordance with an embodiment comprises a computer case 10 and a bracket 20. In one embodiment, the mounting apparatus is used to secure a fan 30. The fan 30 comprises two securing sidewalls 31, 32. Four securing holes 311 are defined in four corners of the securing sidewall 31.

The computer case 10 comprises a bottom plate 11, a side plate 13 connected to a first edge of the bottom plate 11, and a rear plate 15 connected to a second edge of the bottom plate 11. A supporting base 112 is attached to the bottom plate 11 and adjacent to the rear plate 15. The supporting base 112 defines two positioning slots 1121. In one embodiment, each of the two positioning slots 1121 is rectangular, and the two positioning slots 1121 are arranged in a straight line substantially parallel to the rear plate 15.

The rear plate 15 comprises a flange 151 and a securing portion 1511. The securing portion 1511 comprises a connecting panel 1512 and a clamping panel 1514. The connecting panel 1512 is connected to the flange 151 and the clamping panel 1514. In one embodiment, the securing portion 1511 is L-shaped, the connecting panel 1512 is substantially perpendicular to the flange 151 and the clamping panel 1514. A width of the clamping panel 1514, along a direction substantially perpendicular to the rear plate 15, is shorter than a width of the flange 151.

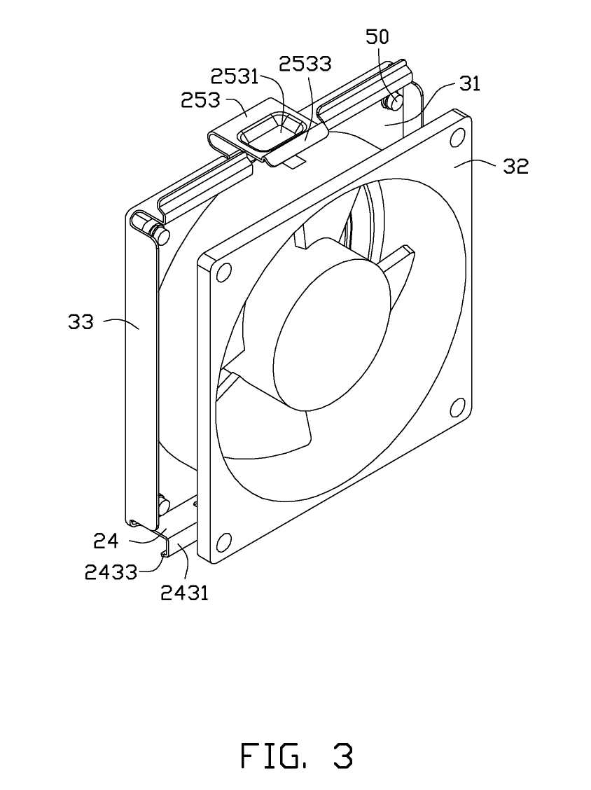

Referring to FIGS. 2-3, the bracket 20 comprises a main body 21, two side panels 23, a bottom panel 24 and a top panel 25. The main body 21 defines a through hole 211 and four mounting holes 213 arranged to four corners of the main body 21. The four mounting holes 213 correspond to the four securing holes 311.

The bottom panel 24 defines two cutouts 241 and two clipping portions 243. A resisting portion 245 is located in each of the two cutouts 241 and includes an extending portion 2451, a connecting portion 2453 and a tab 2455. In one embodiment, the extending portion 2451 and the bottom panel 24 are located in a same plane, and the connecting portion 2453 is substantially perpendicular to the extending portion 2451 and the tab 2455. Each of the two clipping portions 243 is adjacent to each resisting portion 245 and includes a coupling portion 2431 and a clipping piece 2433. In one embodiment, the clipping piece 2433 is slanted relative to the coupling portion 2431.

The top panel 25 includes a mounting flange 251. A mounting portion 253 is located on the mounting flange 251 and defines a concave portion 2531. A hook 2533 extends from the mounting portion 253. In one embodiment, the mounting portion 253 is elastic and U-shaped.

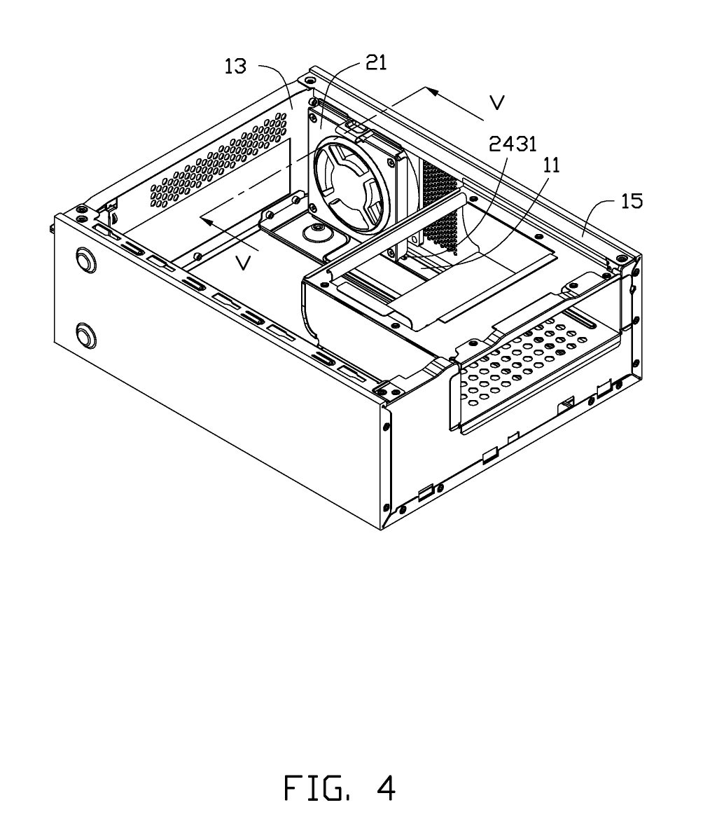

Referring to FIGS. 3-5, in assembly, the main body 21 abuts the securing sidewall 31, and each of the four mounting holes 213 is aligned with each of the four securing holes 311. Four fasteners 50, such as screws, are engaged in each of the mounting holes 213 and each of the securing holes 311, to secure the main body 21 to the securing sidewall 31.

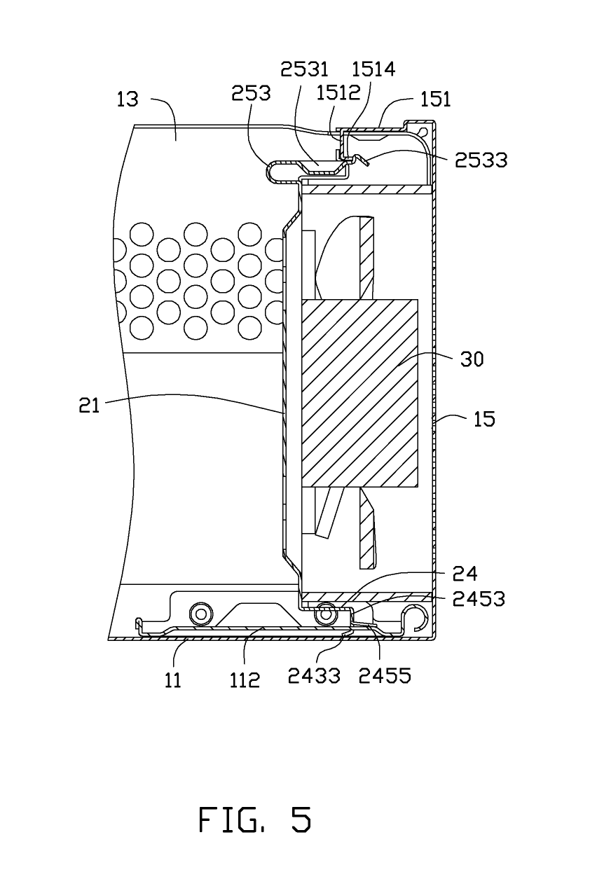

The bracket 20 and the fan 30 are moved in a direction substantially perpendicular to the bottom plate 11. The two clipping portions 243 are inserted into the two positioning slots 1121, and the clipping pieces 2433 abut the bottom plate 11 (shown in FIG. 5). The tabs 2455 abut the supporting base 112, and the hook 2533 abuts the connecting panel 1512. The bracket 20 is pressed towards to the rear plate 15 to deform the mounting portion 253, until the hook 2533 is passed through the connecting panel 1512. The mounting portion 253 is released to engage the hook 2533 to the clamping panel 1514, and the mounting flange 251 abuts the connecting panel 1512. Therefore, the fan 30 may be secured between the bracket 20 and the rear plate 15. In one embodiment, the clamping panel 1514 abuts an outer surface of the hook 2533, and shown in FIG. 5.

In disassembling, the mounting portion 253 is deformed to disengage the hook 2533 from the clamping panel 1514. The bracket 20 is moved away from the rear plate 15, and the mounting portion 253 may be removed from the connecting panel 1512. Each of the two clipping portions 243 is cleared through each of the two positioning slots 1121, and the bracket 20 may be detached from the computer case 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A fan mounting apparatus comprising:
a computer case, the computer case comprising a bottom plate, and a rear plate connected to the bottom plate; the rear plate comprising a flange; and the flange comprising a connecting panel extending towards to the bottom plate, and a clamping panel extending from the connecting panel towards to the bottom plate;
a bracket adapted to secure the fan and comprising a main body, a clipping portion, and a mounting portion; the clipping portion and the mounting portion are located on opposite sides of the main body; the mounting portion comprising a hook;
wherein the clipping portion is attached to the bottom plate, the mounting portion is deformable, the hook has a configuration to extend through the clamping panel when the mounting portion is deformed, and the clamping panel has a configuration to abut on an outer surface of the hook and is adapted to prevent the bracket from moving away from the rear plate.

2. The fan mounting apparatus of claim 1, wherein the connecting panel is substantially perpendicular to the flange and the clamping panel.

3. The fan mounting apparatus of claim 1, wherein a width of the clamping panel, along a direction substantially perpendicular to the rear plate, is shorter than a width of the flange.

4. The fan mounting apparatus of claim 1, the bracket comprises a bottom panel connected to the main body, and a top panel connected to the main body; the clipping portion is located on the bottom panel, and the mounting portion is located on the top panel.

5. The fan mounting apparatus of claim 4, the computer case comprises a supporting base attached to the bottom plate and defines a positioning slot; wherein the clipping portion of the bracket extends through the positioning slot and abuts the bottom plate of the computer case.

6. The fan mounting apparatus of claim 5, the bottom panel of the bracket comprises a resisting portion; the resisting portion has a configuration to abut on a top surface of the supporting base.

7. The fan mounting apparatus of claim 4, the bracket further comprises two side panels;
the two side panels, the bottom panel, and the top panel cooperatively define a space for receiving a sidewall of the fan.

8. The fan mounting apparatus of claim 1, wherein the mounting portion is U-shaped.

9. A fan mounting apparatus comprising:
a computer case comprising a bottom plate and a rear plate connected to the bottom plate; a supporting base attached to the bottom plate and defines a positioning slot; the rear plate comprising a flange, a securing portion extending from the flange towards to the rear plate;
a bracket adapted to secure the fan and comprising a clipping portion, and a mounting portion; the clipping portion and the mounting portion are located on opposite sides of the main body;
wherein the clipping portion extends through the positioning slot and abuts the bottom plate, the mounting portion is deformable and has a configuration to extend through the clamping panel when deformed, and the securing portion has a configuration to abut on an outer surface of the mounting portion and is adapted to prevent the bracket from moving away from the rear plate.

10. The fan mounting apparatus of claim 9, the securing portion of the computer case comprises a connecting panel connected to the flange, and a clamping panel connected to the connecting panel; and the clamping panel has a configuration to engage with the mounting portion of the bracket.

11. The fan mounting apparatus of claim 10, wherein the connecting panel is substantially perpendicular to the flange and the clamping panel.

12. The fan mounting apparatus of claim 10, wherein a width of the clamping panel, along a direction substantially perpendicular to the rear plate, is shorter than a width of the flange.

13. The fan mounting apparatus of claim 9, the bracket comprises a main body, a bottom panel connected to the main body, and a top panel connected to the main body; the clipping portion is located on the bottom panel, and the mounting portion is located on the top panel.

14. The fan mounting apparatus of claim 13, the bracket further comprises two side panels; the two side panels, the bottom panel and the top panel cooperatively define a space for receiving a sidewall of the fan.

15. The fan mounting apparatus of claim 9, the bottom panel of the bracket comprises a resisting portion; the resisting portion has a configuration to abut on a top surface of the supporting base.

16. The fan mounting apparatus of claim 9, wherein the mounting portion further comprises a hook, and the hook has a configuration to engage with the clamping panel.

17. The fan mounting apparatus of claim 9, wherein the mounting portion is U-shaped.

18. The fan mounting apparatus of claim 9, wherein the mounting portion defines a concave portion and the mounting portion is capable of being deformed by the concave portion.
